(19) United States
(12) Patent Application Publication
(10) Pub. No.: US 2006/0131661 A1
(43) Pub. Date: Jun. 22, 2006

(54) Semiconductor device full-wave rectifier circuit and half-wave rectifier circuit

(75) Inventors: Kazutomo Goshima, Ota-shi (JP); Hiroshi Saito, Ota-shi (JP); Yoshiyuki Fukuda, Hanyu-shi (JP); Tsutomu Nakazawa, Isesaki-shi (JP)

Correspondence Address: MORRISON & FOERSTER LLP, 1650 TYSONS BOULEVARD, SUITE 300, MCLEAN, VA, 22102, US

(73) Assignee: SANYO ELECTRIC CO., LTD., Osaka (JP)

(21) Appl. No.: 11/234,871

(22) Filed: Sep. 26, 2005

(30) Foreign Application Priority Data
Sep. 28, 2004 (JP) 2004-280926

(51) Int. Cl. H01L 29/76

(52) U.S. Cl. 257/371

(57) ABSTRACT

Unnecessary leakage current to a semiconductor substrate is prevented when a forward current flows through a diode. An N-type well region is formed in a surface of a P-type semiconductor substrate. A P-type well region is formed in the N-type well region. An N+-type diffusion layer is formed in a surface of the N-type well region outside the P-type well region. A P+-type diffusion layer and an N+-type diffusion layer are formed in a surface of the P-type well region. The N+-type diffusion layer formed in the surface of the N-type well region is electrically connected with the P+-type diffusion layer formed in the surface of the P-type well region with a wiring made of aluminum, for example. An anode electrode is connected with the wiring. Also, a cathode electrode is connected with the N+-type diffusion layer.

### CROSS-REFERENCE OF THE INVENTION

This invention is based on Japanese Patent Application No. 2004-280926, the content of which is incorporated herein by reference in its entirety.

### BACKGROUND OF THE INVENTION

1. Field of the Invention

This invention relates to a semiconductor device, a full-wave rectifier circuit and a half-wave rectifier circuit, which are applicable to a rectifier circuit of an RF (Radio Frequency) tag, for example.

2. Description of the Related Art

The RF tag that can perform information communication with an information processing device using an RF signal (wireless signal) of a predetermined frequency band has been developed in recent years. The RF tag is attached to an object as an identification information media instead of a bar code, and includes an RF circuit, a memory circuit that stores the identification information related to the object, a logic circuit and the like.

In general, an antenna to receive the RF signal is embedded in the RF tag. In the RF tag that is not provided with a battery, the RF signal received by the antenna is converted into a DC (direct current) voltage that is used as a power supply voltage for a circuit embedded in the RF tag.

FIG. 4 shows a power supply circuit for the RF tag. A resonant circuit composed of a coil 51 and a capacitor 52 connected in parallel makes an antenna 50. The RF signal received by the antenna 50 is rectified by a full-wave rectifier circuit 60. The full-wave rectifier circuit 60 includes a first diode D1, a second diode D2, a third diode D3 and a fourth diode D4 connected in a bridge type configuration. The antenna 50 is connected between a connection node IN+ between D1 and D2 and a connection node IN− between D3 and D4. A negative output terminal OUT− is connected with a connection node between D1 and D3, while a positive output terminal OUT+ is connected with a connection node between D2 and D4. The negative output terminal OUT− is generally connected to ground. A full-wave rectified signal is obtained from the positive output terminal OUT+. An output capacitor 61 is connected between the positive output terminal OUT+ and the negative output terminal OUT−.

An operation of the power supply circuit will be explained hereinafter. The external RF signal is received by the antenna 50. The RF signal is an AC (alternating current) signal. During a positive half period (a period during which an electric potential at the node IN+ is higher than an electric potential at the node IN−) of the RF signal, a current flows to charge the output capacitor 61 through a path running through D2, the output capacitor 61 and D3, as indicated by alternate long and short dashed lines in FIG. 4. During a negative half period (a period during which the electric potential at the node IN− is higher than the electric potential at the node IN+) of the RF signal, a current flows to charge the output capacitor 61 through a path running through D4, the output capacitor 61 and D1, as indicated by dashed lines in FIG. 3. Thus the rectification is performed over a whole period of the RF signal, and the output capacitor 61 is charged to a DC (direct current) voltage.

Next, a structure of an integrated circuit chip, that integrates the first diode D1, the second diode D2, the third diode D3 and the fourth diode D4, will be described referring to FIG. 5 and FIG. 6.

FIG. 5 is a cross-sectional view showing a structure of the second diode D2 and the fourth diode D4. An N-type well region 11 is formed in a surface of a P-type semiconductor substrate 10. A P+-type diffusion layer 12 and an N+-type diffusion layer 13 are formed in a surface of the N-type well region 11. An anode electrode 14 is connected with the P+-type diffusion layer 12 while a cathode electrode 15 is connected with the N+-type diffusion layer 13, forming a PN diode structure.

FIG. 6 is a cross-sectional view showing a structure of the first diode D1 and the third diode D3. A P-type well region 21 is formed in the surface of the P-type semiconductor substrate 10. An N+-type diffusion layer 22 and a P+-type diffusion layer 23 are formed in a surface of the P-type well region 21. A cathode electrode 24 is connected with the N+-type diffusion layer 22 while an anode electrode 25 is connected with the P+-type diffusion layer 23, forming a PN diode structure. The P-type semiconductor substrate 10 makes a part of the anode in this structure. The P-type semiconductor substrate 10 is generally connected to the ground.

Further information on the technologies described above is disclosed in Japanese Patent Application Publication Nos. H08-251925 and H08-88586, for example.

Because an electric potential at the anode of the second diode D2 or the fourth diode D4 may become higher than an electric potential at the P-type semiconductor substrate 10, the diodes are formed in the N-type well region 11 formed in the surface of the P-type semiconductor substrate 10 as shown in FIG. 5, in order that the full-wave rectifier circuit operates correctly.

With the structure of FIG. 5, however, a parasitic bipolar transistor is formed of the P+-type diffusion layer 12 that serves as an emitter, the N+-type diffusion layer 13 and the N-type well region 11 that serve as a base and the P-type semiconductor substrate 10 that serves as a collector. When a forward current of the diode flows from the anode electrode 14 to the cathode electrode 15, the parasitic bipolar transistor is turned on because the forward current serves as a base current I_{B} of the parasitic bipolar transistor.

As a result, a collector current I_{C} flows from the P+-type diffusion layer 12 (emitter) to the P-type semiconductor substrate 10 (collector) as a leakage current. Since the collector current I_{C} does not contribute charging the output capacitor 61, it causes a problem that power efficiency of the full-wave rectifier circuit is reduced. As for the first diode D1 and the third diode D3, the problem described above is not caused, because there is no parasitic bipolar transistor as shown in FIG. 6.

Also, a parasitic thyristor is formed when the second diode D2 shown in FIG. 5 and the third diode D3 shown in FIG. 6 are formed in the common P-type semiconductor substrate 10.

The parasitic thyristor may be turned on to cause a latch-up. The latch-up causes problems such as reduction in the power efficiency and malfunction of the full-wave rectifier circuit.

### SUMMARY OF THE INVENTION

A semiconductor device of this invention includes a semiconductor substrate of a first conductivity type, a first well region of a second conductivity type formed in a surface of the semiconductor substrate, a second well region of the first conductivity type formed in the first well region, a first diffusion layer of the second conductivity type formed in a surface of the first well region, a second diffusion layer of the first conductivity type formed in a surface of the second well region and a third diffusion layer of the second conductivity type formed in the surface of the second well region, wherein the first diffusion layer and the second diffusion layer are electrically connected.

A full-wave rectifier circuit of this invention includes four rectifying devices connected in a bridge type configuration, and at least one of the four rectifying devices includes a semiconductor substrate of a first conductivity type, a first well region of a second conductivity type formed in a surface of the semiconductor substrate, a second well region of the first conductivity type formed in the first well region, a first diffusion layer of the second conductivity type formed in a surface of the first well region, a second diffusion layer of the first conductivity type formed in a surface of the second well region and a third diffusion layer of the second conductivity type formed in the surface of the second well region, wherein the first diffusion layer and the second diffusion layer are electrically connected.

A half-wave rectifier circuit of this invention includes a rectifying device that includes a semiconductor substrate of a first conductivity type, a first well region of a second conductivity type formed in a surface of the semiconductor substrate, a second well region of the first conductivity type formed in the first well region, a first diffusion layer of the second conductivity type formed in a surface of the first well region, a second diffusion layer of the first conductivity type formed in a surface of the second well region and a third diffusion layer of the second conductivity type formed in the surface of the second well region, wherein the first diffusion layer and the second diffusion layer are electrically connected.

### BRIEF DESCRIPTION OF THE DRAWINGS

FIG. 1 is a cross-sectional view showing a structure of a semiconductor device of this invention.

FIG. 2 is a circuit diagram showing a half-wave rectifier circuit of this invention.

FIG. 3 is a cross-sectional view showing a structure of a semiconductor device of this invention.

FIG. 4 is a circuit diagram showing a full-wave rectifier circuit.

FIG. 5 is a cross-sectional view showing a semiconductor device according to a prior art.

FIG. 6 is a cross-sectional view showing a semiconductor device according to the prior art.

### DETAILED DESCRIPTION OF THE INVENTION

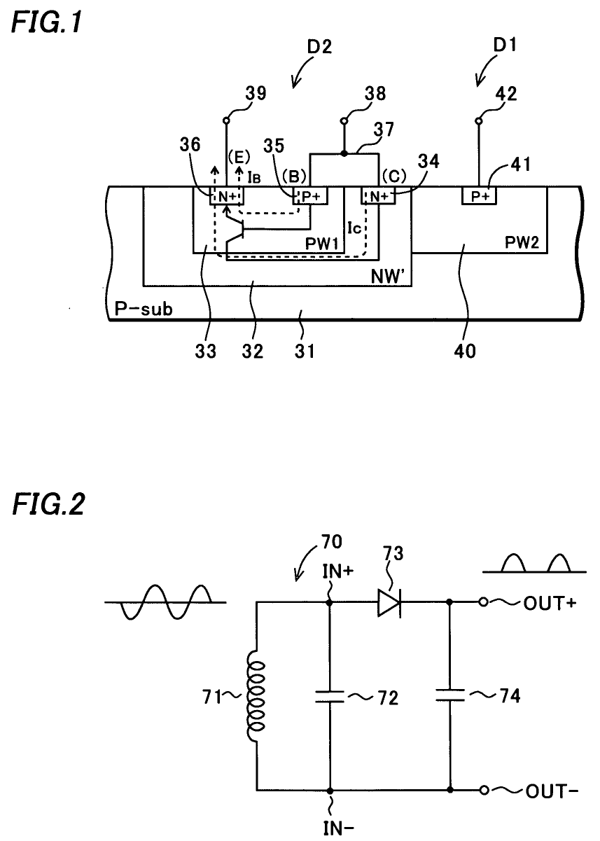

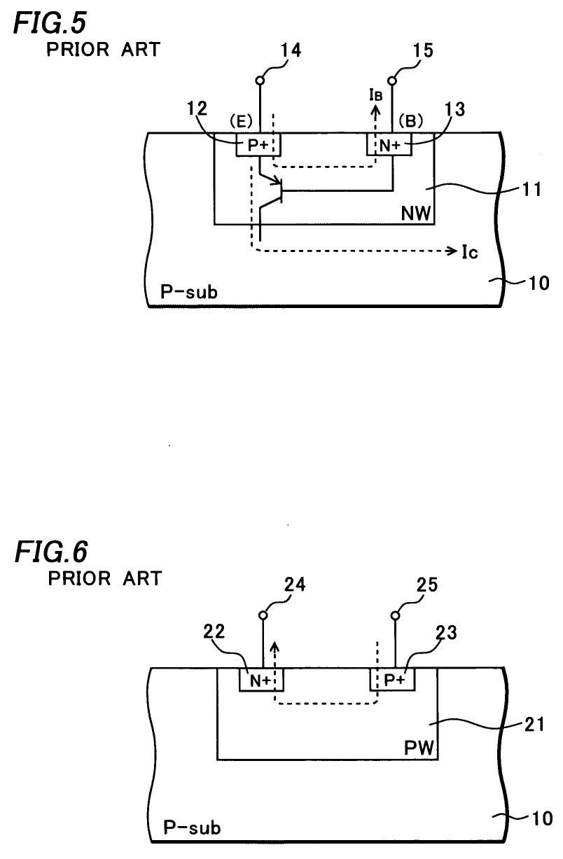

Next, a full-wave rectifier circuit of this invention and a structure of diodes used in it are described. The circuit design of the full-wave rectifier circuit is the same as shown in FIG. 4. However, the structure of a second diode D2 and the structure of a fourth diode D4 are different from the structure shown in FIG. 5. Since the fourth diode D4 may adopt the same structure as the structure of the second diode D2, only the structure of the second diode D2 is described hereafter referring to FIG. 1.

An N-type well region 32 is formed in a surface of a P-type semiconductor substrate 31. A P-type well region 33 is formed in the N-type well region 32. That is, the P-type well region 33 is formed shallower than the N-type well region 32. An N+-type diffusion layer 34 is formed in a surface of the N-type well region 32 outside the P-type well region 33. And a P+-type diffusion layer 35 and an N+-type diffusion layer 36 are formed in a surface of the P-type well region 33.

The N+-type diffusion layer 34 formed in the surface of the N-type well region 32 is electrically connected with the P+-type diffusion layer 35 formed in the surface of the P-type well region 33 with a wiring 37 made of aluminum, for example. An anode electrode 38 is connected with the wiring 37. Also, a cathode electrode 39 is connected with the N+-type diffusion layer 36. The P-type semiconductor substrate 31 is preferably connected to ground. A PN diode is formed of the P+-type diffusion layer 35, the P-type well region 33 and the N+-type diffusion layer 36.

A parasitic bipolar transistor is formed of the N+-type diffusion layer 36 that serves as an emitter, the P+-type diffusion layer 35 and the P-type well region 33 that serve as a base and the N+-type diffusion layer 34 that serves as a collector. When a forward current of the diode flows from the anode electrode 38 to the cathode electrode 39, the parasitic bipolar transistor is turned on because the forward current serves as a base current I_{B} of the parasitic bipolar transistor.

A collector current I_{C} from the N+-type diffusion layer 34 flows into the P-type well region 33 and further to the N+-type diffusion layer 36 that serves as the emitter, and eventually flows into the cathode electrode 39. Therefore, a power efficiency of the full-wave rectifier circuit improves because the current does not leak into the P-type semiconductor substrate 31 as in the prior art. Also, a latch-up is not caused as in the prior art.

In addition to the second diode D2, a first diode D1 that is connected in series to the second diode D2 can be formed by forming a P+-type diffusion layer 41 in the surface of the P-type semiconductor substrate 31 adjacent the N-type well region 32. Although the P+-type diffusion layer 41 is formed in a surface of a P-type well region 40 that is formed adjacent the N-type well region 32 in FIG. 1, the P-type well region 40 may be omitted. An anode electrode 42 of the first diode D1 is connected with the P+-type diffusion layer 41. The N+-type diffusion layer 34 formed in the surface of the N-type well region 32 is also used as a cathode of the first diode D1.

Therefore, according to the structure described above, by forming the N-type well region 32, the first diode D1 can be formed adjacent to it with no additional process step. Further one of the merits of the structure described above is that pattering area for the first and second diodes D1 and D2 can be reduced. The structure of the first and second diodes D1 and D2 described above can be applied as a structure of the third and fourth diodes D3 and D4 without modification.

Next, a second embodiment, a half-wave rectifier circuit, of this invention and a structure of a diode used in it are described. FIG. 2 is a circuit diagram showing the half-wave rectifier circuit. A resonant circuit composed of a coil 71 and a capacitor 72 connected in parallel makes an antenna 70. The RF signal received by the antenna 70 is rectified by the half-wave rectifier circuit that includes the diode 73. An output capacitor 74 is connected between a positive output terminal OUT+ and a negative output terminal OUT−. Similar to the full-wave rectifier circuit, the half-wave rectifier circuit may be used as the power supply circuit for the RF tag.

An operation of the circuit will be explained hereinafter. The negative output terminal OUT− is connected to the ground. When the external RF signal is received by the antenna 70, a forward current flows through the diode 73 to charge the output capacitor 74 during a positive half period (a period during which an electric potential at the node IN+ is higher than an electric potential at the node IN−) of the RF signal. Since the diode 73 is reverse biased during a negative half period (a period during which the electric potential at the node IN− is higher than the electric potential at the node IN+) of the RF signal, no forward current flows through the diode and the output capacitor 74 is not charged during the negative half period. As a result, a DC voltage that is a half-wave rectified signal appears on the output terminal OUT+.

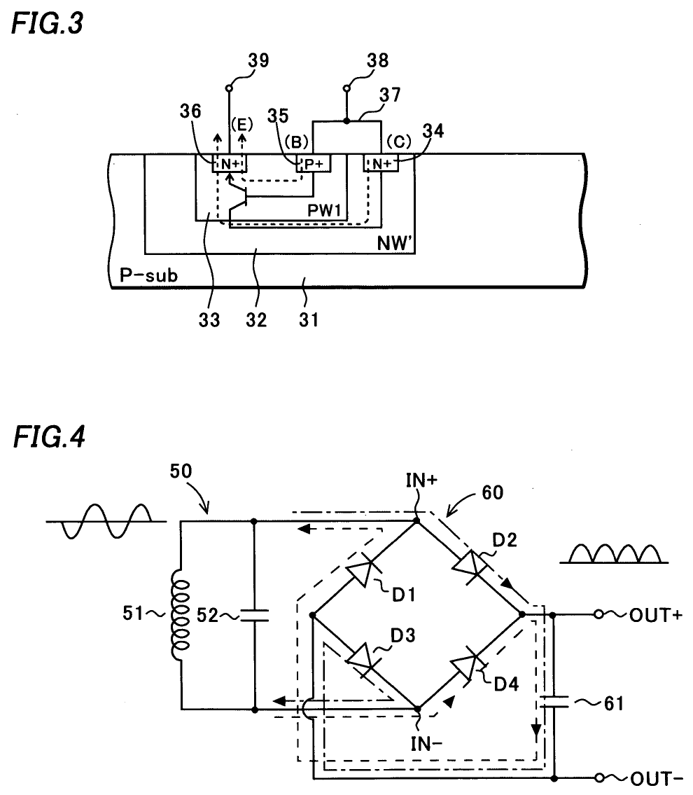

If the diode having the structure shown in FIG. 5 is used as the diode 73, the collector current I_{C} flows from the P+-type diffusion layer 12 (emitter) to the P-type semiconductor substrate 10 (collector) as a leakage current that does not contribute to charging the output capacitor 74, as in the case of the full-wave rectifier circuit. Therefore a power efficiency of the half-wave rectifier circuit is reduced. By forming the diode 73 having the structure shown in FIG. 3, which is the same structure as the second diode D2 shown in FIG. 1, the leakage current to the P-type semiconductor substrate 31 is prevented and the power efficiency of the half-wave rectifier circuit is improved.

According to the semiconductor device of this invention, the leakage current to the semiconductor substrate can be prevented when the forward current flows through the diode. Also the latch-up can be prevented. Thus the power efficiency of the rectifier circuit can be improved by using the semiconductor device of this invention as the rectifying device in the rectifier circuit.

Also, according to the full-wave rectifier circuit of this invention, the leakage current to the semiconductor substrate can be prevented when the forward current flows through the rectifying device (diode), and the power efficiency of the full-wave rectifier circuit is improved.

According to the half-wave rectifier circuit of this invention, the leakage current to the semiconductor substrate can be prevented when the forward current flows through the rectifying device (diode), and the power efficiency of the half-wave rectifier circuit is improved.

What is claimed is:

1. A semiconductor device comprising:
a semiconductor substrate of a first general conductivity type;
a first well region of a second general conductivity type disposed in a surface region of the semiconductor substrate;
a second well region of the first general conductivity type disposed in the first well region;
a first diffusion layer of the second general conductivity type disposed in the first well region;
a second diffusion layer of the first general conductivity type disposed in the second well region; and
a third diffusion layer of the second general conductivity type disposed in the second well region,
wherein the first diffusion layer and the second diffusion layer are electrically connected.

2. The semiconductor device of claim 1, further comprising a fourth diffusion layer of the first general conductivity type disposed adjacent the first well and in the surface region of the semiconductor substrate.

3. A full-wave rectifier circuit comprising:
four rectifying devices that are connected in a bridge configuration,
wherein at least one of the rectifying devices comprising;
a semiconductor substrate of a first general conductivity type,
a first well region of a second general conductivity type disposed in a surface region of the semiconductor substrate,
a second well region of the first general conductivity type disposed in the first well region,
a first diffusion layer of the second general conductivity type disposed in the first well region,
a second diffusion layer of the first general conductivity type that is disposed in the second well region and electrically connected with the first diffusion layer, and
a third diffusion layer of the second general conductivity type disposed in the second well region.

4. The full-wave rectifier circuit of claim 3, the one of the rectifying devices further comprising a fourth diffusion layer of the first general conductivity type disposed adjacent the first well and in the surface region of the semiconductor substrate.

5. A half-wave rectifier circuit comprising:
a semiconductor substrate of a first general conductivity type;
a first well region of a second general conductivity type disposed in a surface region of the semiconductor substrate;
a second well region of the first general conductivity type disposed in the first well region;
a first diffusion layer of the second general conductivity type disposed in the first well region;
a second diffusion layer of the first general conductivity type that is disposed in the second well region and electrically connected with the first diffusion layer;
a third diffusion layer of the second general conductivity type disposed in the second well region; and
an output capacitor electrically connected with the third diffusion layer.
